(19) United States
(12) Patent Application Publication
(10) Pub. No.: US 2026/0090298 A1
(43) Pub. Date: Mar. 26, 2026

(54) SILICON WAFER WITH LASER MARK AND MANUFACTURING METHOD OF THE SAME

(71) Applicant: SUMCO CORPORATION, Tokyo (JP)

(72) Inventors: Yuki NAKASHIMA, Tokyo (JP); Yoichiro HIRAKAWA, Tokyo (JP)

(73) Assignee: SUMCO CORPORATION, Tokyo (JP)

(21) Appl. No.: 19/130,656

(22) PCT Filed: Aug. 10, 2023
(86) PCT No.: PCT/JP2023/029325

§ 371 Date: May 16, 2025

(30) Foreign Application Priority Data
Nov. 22, 2022 (JP) 2022-186656

(51) Int. Cl. H10P 34/42; H10D 62/40

(52) U.S. Cl. CPC H10P 34/42; H10D 62/405; H10P 50/642; H10P 52/402; H10W 46/401

(57) ABSTRACT

In order to have uniform dot holes even when a deep laser mark of approximately 100 μm depth is formed, a silicon wafer having a crystal plane orientation of (100) has an identification mark configured by a plurality of dot holes on a surface with a surface roughness of 0.15 to 0.60 nm. A ratio between a length in a <100> direction and a length in a <110> direction of an opening of the dot hole on a wafer surface is 1 to 1.10, the length in the <100> direction of the opening is 80 μm to 110 μm, a depth of the dot hole in a cross-section is 80 μm to 110 μm, and a bottom surface of the dot hole is a flat surface of a (100) plane.

### FIELD OF THE INVENTION

The present invention relates to a silicon wafer with a laser mark and a manufacturing method of the same.

### BACKGROUND OF THE INVENTION

An identification mark is often printed by irradiating laser light on an outer periphery such as a back surface of a silicon wafer to manage or identify the wafer. The mark printed by the laser light (hereafter, referred to as a laser mark) is configured with characters and symbols formed of an aggregate of a plurality of dot holes (recesses) and is known to be large enough to be identified visually or by a camera and the like.

As a laser mark of this type, a mark formed of dot holes that are shaped suitable for removing a residue such as a photoresist is known, and the mark includes each mark element that forms a stop hole on a substrate, and a sidewall having an upper sidewall portion with an upper sidewall angle and a lower sidewall portion with a lower sidewall angle, where an upper sidewall angle β is smaller than a lower sidewall angle δ, and a depth D is approximately 12 μm or less (see FIG. 2 in Patent Literature 1).

### RELATED ART

### Patent Literature

Patent Literature 1: US Publication No. 2008/0135981

### SUMMARY OF THE INVENTION

### Problems to be Solved by the Invention

In the above conventional technology, an etching anisotropy of silicon crystal is not mentioned with respect to the shape of the dot holes configuring the laser mark, and therefore, the above angles β and δ are assumed to be the same angle in all directions. Accordingly, the shape of the upper dot hole is supposed to be circular, which requires an acid etching without crystal orientation dependence in order to achieve this. However, a method of forming a laser mark by the acid etching causes the dot holes to become uneven due to a high etching speed when forming a deep laser mark of approximately 100 μm depth.

The present invention undertakes to solve the issue of providing, even when a deep laser mark of approximately 100 μm depth is formed, a silicon wafer with a laser mark having uniform dot holes and a manufacturing method thereof.

### Means for Solving the Problems

The present invention provides a silicon wafer having a crystal plane orientation of (100), which has an identification mark configured by a plurality of dot holes on a surface with a surface roughness of 0.15 to 0.60 nm. The above concerns are solved by the silicon wafer with a laser mark where a ratio between a length in a <100> direction and a length in a <110> direction of an opening of the dot hole on a wafer surface is 1 to 1.10, and the length in the <100> direction of the opening is 80 μm to 110 μm, a depth of the dot hole in a cross-section is 80 μm to 110 μm, and a bottom surface of the dot hole is a flat surface of a (100) plane.

In the present invention, more preferably, an angle that is formed by a side surface and the wafer surface is 63 to 73 degrees in the cross-section in the <110> direction of the dot hole.

In the present invention, more preferably, an angle that is formed by the side surface and the wafer surface is 56 to 70 degrees in the cross-section in the <100> direction of the dot hole.

In the present invention, an projection height of the opening of the dot hole on the wafer surface can be less than 25 nm from the wafer surface.

In the present invention, the projection height of the opening of the dot hole on the wafer surface can also be 30 nm or more from the wafer surface.

The present invention also resolves the above concerns by a manufacturing method of the silicon wafer with the laser mark, where laser light is irradiated on the wafer surface of the silicon wafer having the crystal plane orientation of (100) to form a stop hole with a depth of 80 μm to 110 μm, after which the silicon wafer is immersed in a potassium hydroxide solution with a concentration of 40 wt % or more to perform etching of the wafer surface and the stop holes only by 5 to 15 μm thickness, and then the wafer surface is polished.

In the present invention, when irradiating the laser light on the wafer surface, it is possible to irradiate the laser light with a first beam diameter, after which the laser light with a second beam diameter that is smaller than the first beam diameter is irradiated, or to irradiate the laser light with the second beam diameter, after which the laser light with the first beam diameter is irradiated.

In the present invention, when irradiating the laser light on the wafer surface, the laser light may be irradiated with a single beam diameter.

### Effect of the Invention

According to the present invention, since an anisotropic etching of silicon crystal is used to form the identification mark configured with a plurality of dot holes, the silicon wafer with the laser mark having uniform dot holes can be obtained even when a deep laser mark of approximately 100 μm depth is formed.

### BRIEF DESCRIPTION OF THE DRAWINGS

FIG. 1 is a front view illustrating an embodiment of a silicon wafer with a laser mark according to the present invention.

FIG. 2 is a flow chart illustrating an embodiment of a manufacturing method of the silicon wafer with the laser mark according to the present invention.

FIG. 3A is a front view and a cross-sectional view along a IIIA-IIIA line of a wafer illustrating an example of a laser irradiation step in FIG. 2.

FIG. 3B is a front view and a cross-sectional view along a IIIB-IIIB line of the wafer illustrating another example of the laser irradiation step in FIG. 2.

FIG. 4 is a front view illustrating the wafer that has completed an alkaline etching step in FIG. 2.

FIG. 5 is a cross-sectional view along a V-V line in FIG. 4.

FIG. 6 is a cross-sectional view along a VI-VI line in FIG. 4.

FIG. 7 is a cross-sectional view illustrating the wafer that has completed a polishing step in FIG. 2.

FIG. 8 shows a crystal structure of a silicon single crystal.

FIG. 9 is a cross-sectional view along a <110> direction when the anisotropic etching is performed on a dot hole formed on the silicon wafer having a crystal plane orientation of (100).

FIG. 10 is a cross-sectional view along a <100> direction when the anisotropic etching is performed on a dot hole formed on the silicon wafer having the crystal plane orientation of (100).

FIG. 11 is a binarized photo where the dot hole in Examples and Comparative Example is observed in a front view.

### MODE FOR CARRYING OUT THE INVENTION

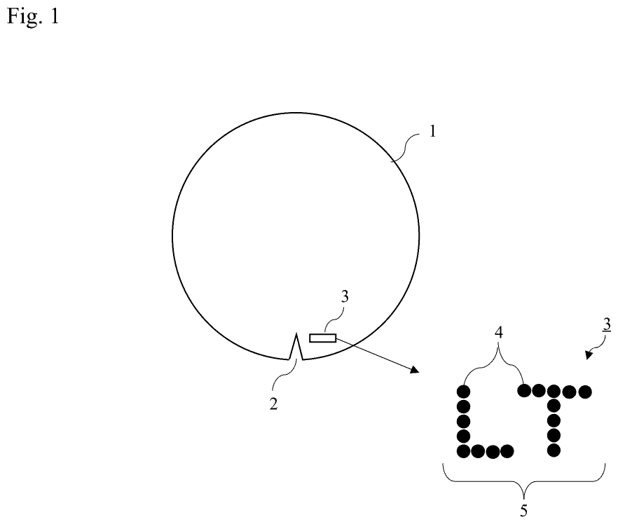

FIG. 1 is a front view illustrating an embodiment of a silicon wafer with a laser mark according to the present invention. In a silicon wafer 1 illustrated in FIG. 1, a notch 2 formed by a V-shaped cutout is provided in one location on an outer circumference of the silicon wafer 1 in order to align an orientation of the silicon wafer 1 in a manufacturing process and the like of a semiconductor device. In addition, the silicon wafer 1 illustrated in the drawing is provided with a laser mark printed portion 3 near the notch 2 to identify an individual wafer. The size of the laser mark printed portion 3 of this example is not particularly limited, but is approximately 2 mm×20 mm or 1.6 mm×16 mm, for example.

In the laser mark printed portion 3, as shown with an expansion in the drawing, a plurality of dot holes 4 shot by irradiated laser light are formed, and an aggregate of the plural dot holes 4 creates a printed identification mark comprising of a character, bar code, and the like. The character, bar code, and the like printed by the laser mark printed portion 3 are read in each process such as the semiconductor device manufacturing process and used to identify the quality and the like of the laser wafer 1. In the present specification, the recessed stop hole formed with one shot of laser light is called the dot hole 4, the character, bar code, and the like configured with a plurality of dot holes 4 is called an identification mark 5 (or a laser mark), and the silicon wafer 1 provided with the laser mark printed portion 3 is called the silicon wafer with the laser mark according to the present invention.

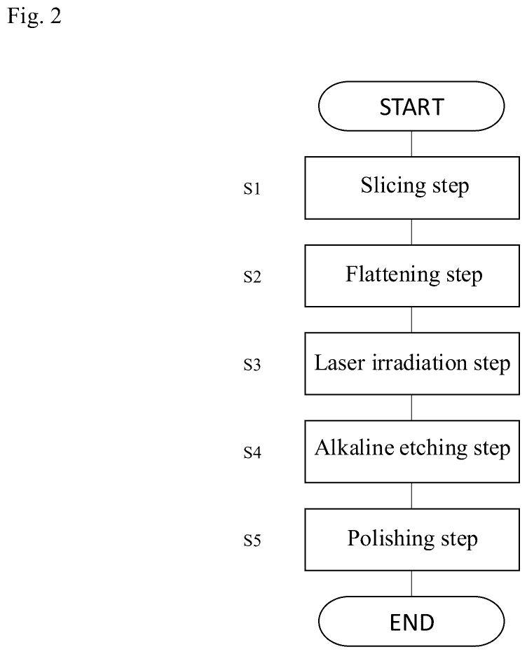

FIG. 2 is a flow chart illustrating an embodiment of a manufacturing method of the silicon wafer with the laser mark according to the present invention. The manufacturing method of the silicon wafer with the laser mark of the present embodiment includes a slicing step (step S1) cutting out a disk-shaped wafer from a single crystal ingot; a flattening step (step S2) equalizing thickness of the cutout disk-shaped wafer; a laser irradiation step (step S3) irradiating laser light at the laser mark printing portion 3 on a surface of the wafer, of which the thickness is equalized, in order to form an original shape 41 of the plurality of dot holes 4; an alkaline etching step (step S4) performing an etching process, using an alkaline etchant, on the wafer surface that includes the laser mark printed portion 3 in which at least the original shape 41 of the dot hole 4 is formed and then performing the etching process of the original shape 41 of the dot hole 4 to the dot hole 4; and a polishing step (step S5) polishing the wafer surface after the etching process with a polishing solution containing abrasive grains.

The slicing step in step S1 of the present embodiment is a step of cutting out the disk-shaped wafer by cutting a crystalline ingot through supplying grinding fluid using a wire saw in contact with the crystalline ingot, or by cutting the crystalline ingot using a circumferential blade. The silicon wafer of the present embodiment is a silicon single crystal wafer having a crystal plane orientation of (100).

The flattening step in step S2 of the present embodiment is a step of improving flatness of the wafer and bringing the wafer thickness closer to the final thickness by lapping the wafer surface cut out in the slicing step. Lapping can be performed using loose abrasive grains in a range of #1000 to 1500, for example. Also, instead of lapping, by a grinding process using a surface grinding machine or a double-disk simultaneous surface grinding machine, variation and wave of the wafer thickness may be reduced by flattening the wafer more accurately. Lapping may be performed on both surfaces of the wafer or only on a single surface, but lapping both surfaces of the wafer is more preferred in view of flatness.

The laser irradiation step in step S3 of the present embodiment shot-irradiates the laser light output from a laser source to the laser mark printed portion 3 multiple times intermittently, and forms the original shape 41 of a plurality of dot holes 4. The original shape 41 of the dot hole 4 formed in this example is what is known as a stop hole having a bottom surface, side surface, and opening. The original shape 41 of the dot hole 4 is the stop hole itself that is formed by irradiating the laser light, and is a state before performing a process of the alkaline etching step in step S4. These plural dot holes 4 configure a pattern such as a character, graphic, and symbol that eventually become the identification mark 5. The identification mark 5 may be formed on a front or back surface of the silicon wafer 1, but the back surface of the wafer with a surface roughness of 0.15 to 0.60 nm is more preferred. The surface roughness described here is a root mean square roughness Rq when a range of 10 μm×10 μm is measured using an Atomic Force Microscope (AFM).

The laser light used in this step is not particularly limited and can be an infrared laser, CO₂ laser, YLE laser, Nd:YAG laser, and the like. Since a depth D of the dot hole 4 of the present embodiment is 80 μm to 110 μm, the depth of the original shape 41 of the dot hole 4 formed in the laser irradiation step has a shallow measurement only by an allowance (5 μm to 15 μm) in the following alkaline etching step. For example, when a target value of the depth D of the final dot hole 4 is 100 μm and the allowance in the following alkaline etching step is 5 μm to 15 μm, the depth of the original shape 41 of the dot hole 4 formed in the laser irradiation step is 85 μm to 95 μm. The depth of the original shape 41 of the dot hole 4 formed by irradiating the laser light does not depend on the output of the laser light, but correlates to the number of laser light shot (or irradiating time), and therefore, multiple shots are performed when the desired depth cannot be obtained with a single shot.

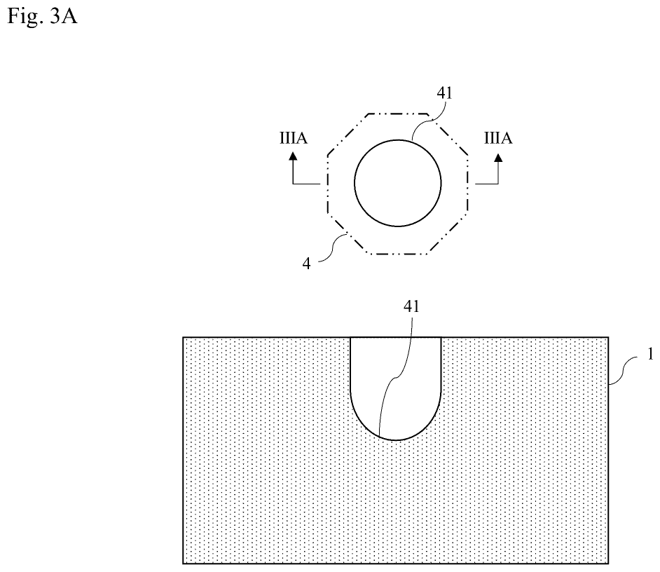

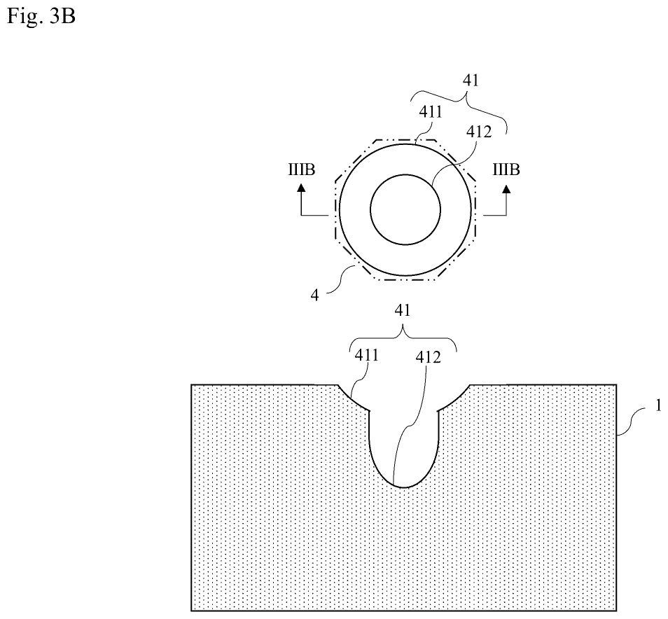

FIG. 3A is a front view (top view) and a cross-sectional view (bottom view) along a IIIA-IIIA line of the processed silicon wafer 1 illustrating an example of the laser irradiation step of step S4 in FIG. 2. In this example, the original shape 41 of the dot hole 4 is formed only by the laser light with the single beam diameter. The beam diameter of the laser light in this example is not particularly limited, but the length in the <100> direction of an opening 42 of the final dot hole 4 is 80 μm to 110 μm and the ratio between the length in <100> direction and the length in <110> direction is 1 to 1.10, and therefore, the measurement is smaller only by the allowance (5 μm to 15 μm) in the following alkaline etching step. For example, when the target value of the length in the <100> direction of the opening 42 of the final dot hole 4 is 100 μm, the target value of the length in the <110> direction of the opening 42 is 100 μm, and the allowance in the following alkaline etching step is 5 μm to 15 μm, the beam diameter of the laser light can be approximately 85 to 95 μm.

FIG. 3B is a front view (top view) and a cross-sectional view (bottom view) along a IIIB-IIIB line of the processed silicon wafer 1 illustrating another example of the laser irradiation step of step S4 in FIG. 2. In this example, the original shape 41 of the dot hole 4 is formed using the laser light with different beam diameter. For example, the laser light with a first beam diameter having a relatively large beam diameter is first irradiated to form a first original shape 411 of the dot hole 4, and then the laser light with a second beam diameter having a relatively small beam diameter is irradiated to form a second original shape 412 of the dot hole 4. Alternatively, the laser light with the second beam diameter having a relatively small beam light may first be irradiated to form the second original shape 412 of the dot hole 4, and then the laser light with the first beam diameter having a relatively large beam diameter is irradiated to form the first original shape 411 of the dot hole 4. In this way, in the original shape 41 of the dot hole 4, by forming a side surface with a small inclination such as the first original shape 411, when the process of the polishing step is finished, a projection height h of the opening 42 of the dot hole 4 can be inhibited from being high. This is described later. The beam diameter of the laser light can be controlled by output and current value of the laser light, and the beam diameter can be increased by increasing the output of the laser light.

Returning to FIG. 2, the alkaline etching step in step S4 of the present embodiment is a step of immersing, the silicon wafer 1, in which the original shape 41 of a plurality of dot holes 4 is formed, in a highly concentrated potassium hydroxide solution with a concentration of 40 wt % or more, and performing an anisotropic etching process between the wafer surface 11 and the original shape 41 of the dot holes 4. The etching allowance here is not particularly limited, but approximately 5 to 15 μm thickness is more preferable. By limiting the thickness of the etching allowance in this range, the shape of the opening 42 can be controlled to a predetermined shape.

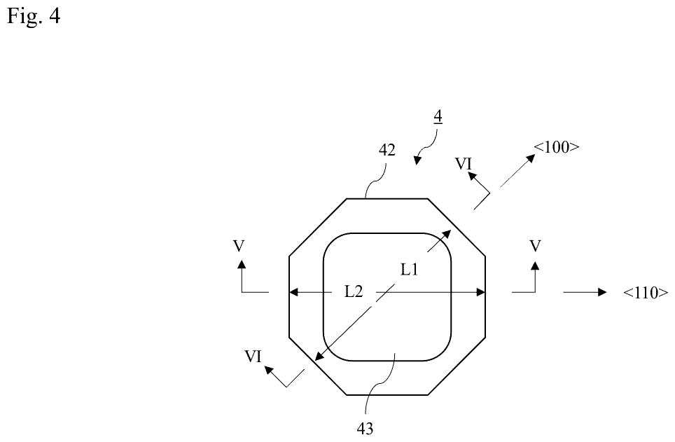

As shown in FIG. 4, in the final dot hole 4 of the present embodiment, a ratio between a length L1 in the <100> direction and a length L2 in the <110> direction of the opening 42 of the dot hole 4 on the wafer surface 11 is 1 to 1.10, the length L1 in the <100> direction of the opening 42 is 80 μm to 110 μm, the depth D of the dot hole 4 in the cross-section is 80 μm to 110 μm, and a bottom surface 43 of the dot hole 4 is a flat surface of the (100) plane.

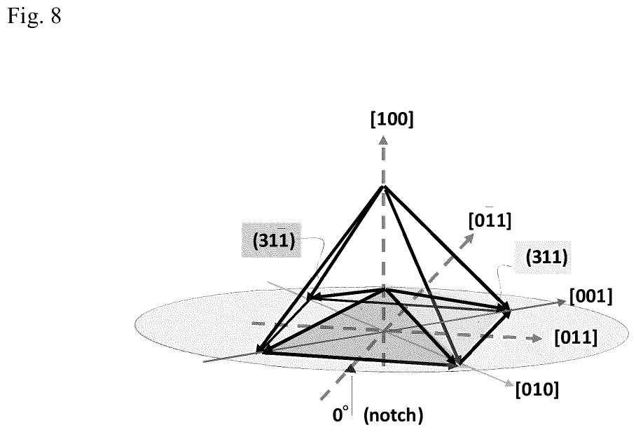

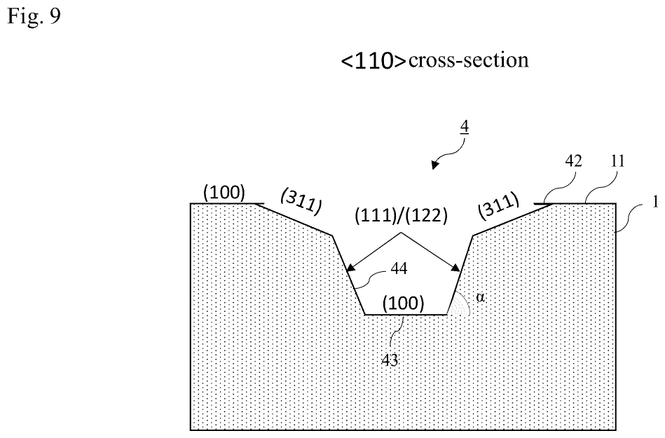

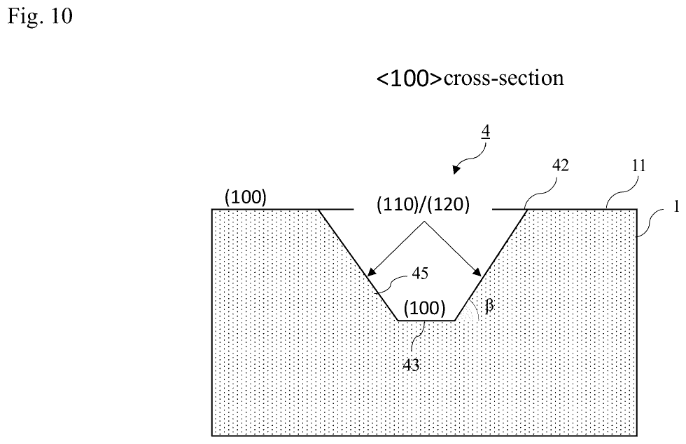

FIG. 8 shows the crystal structure of the silicon single crystal wafer having the crystal plane orientation of (100), FIG. 9 is a cross-sectional view along the <110> direction when the stop hole is formed in the silicon wafer 1 having the crystal plane orientation of (100) and the anisotropic etching is performed thereof, and FIG. 10 is the similar cross-sectional view along the <100> direction. As shown in FIGS. 9 and 10, when the stop hole (dot hole 4) is formed in the silicon wafer 1 having the crystal plane orientation of (100) and the anisotropic etching is performed using a highly concentrated alkaline etchant, the bottom surface 43 of the stop hole (dot hole 4) becomes the (100) plane. Also, as shown in FIG. 9, in the cross-sectional view along the <110> direction, both side surfaces 44 of the bottom surface 43 are a (111) plane or a (122) plane, which continue to a (311) plane. On the other hand, as shown in FIG. 10, in the cross-sectional view along the <100> direction, both side surfaces 45 of the bottom surface 43 are a (110) plane or a (120) plane.

In addition, as shown in FIG. 9, in the cross-section along the <110> direction, when the (111) plane appears on the side surface 44, an angle α that is formed by the bottom surface 43 of the (100) plane and the side surface 44 of the (111) plane is 54 degrees, and when the (122) plane appears on the side surface, the angle α that is formed by the bottom surface 43 of the (100) plane and the side surface 44 of the (122) plane is 70 degrees. An angle that is formed by the bottom surface 43 of the (100) plane and the side surface 44 of the (311) plane is 25 degrees. In addition, as shown in FIG. 10, in the cross-section along the <100> direction, when the (110) plane appears on the side surface 45, an angle β that is formed by the bottom surface 43 of the (100) plane and the side surface 45 of the (110) plane is 45 degrees, and when the (120) plane appears on the side surface, the angle β that is formed by the bottom surface 43 of the (100) plane and the side surface 45 of the (120) plane is 64 degrees.

In this way, when the stop hole (dot hole 4) is formed in the silicon wafer 1 having the crystal plane orientation of (100) plane and the anisotropic etching is performed using a highly concentrated alkaline etchant, a crystal face with a relatively low etching rate appears and compared to the acid etching, the dot hole 4 having a shape with less variations can be obtained.

Therefore, in the alkaline etching step (step S4) of the present embodiment, etching is performed so that the dot holes 4 are along each crystal face illustrated in FIGS. 9 and 10. However, the dot holes 4 of the present embodiment do not need to be the dot holes 4 that are formed by a complete crystal face as shown in FIGS. 9 and 10, and the etching process can be performed with an appropriate allowance so that a portion of each of these crystal faces appears.

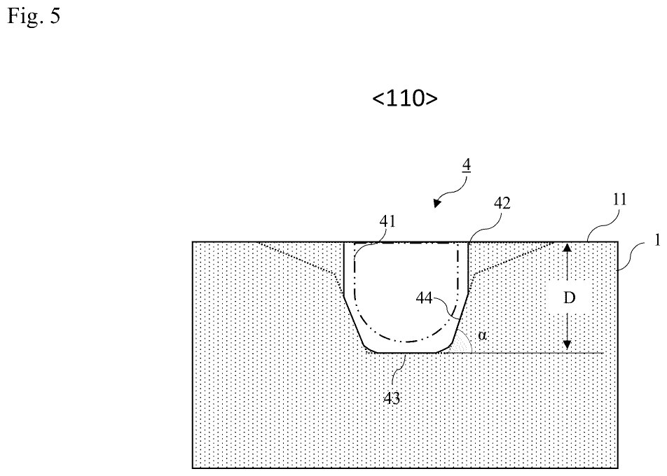

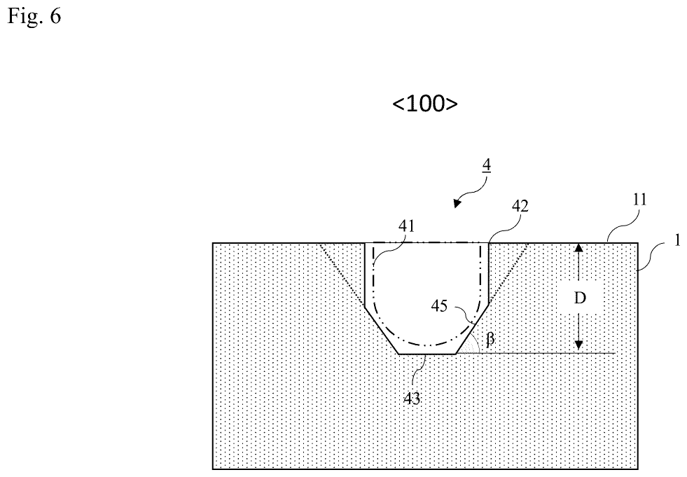

FIG. 4 is the front view illustrating the wafer that has undergone the alkaline etching step S4 in FIG. 2, FIG. 5 is the cross-sectional view along the V-V line in FIG. 4, and FIG. 6 is the cross-sectional view along the VI-VI line in FIG. 4. FIG. 5 is also the cross-sectional view along the <110> direction of the silicon wafer 1 having the crystal plane orientation of (100) plane, and FIG. 6 is a similar cross-sectional view along the <100> direction. In the final dot hole 4 of the present embodiment, the ratio between the length L1 in the <100> direction and the length L2 in the <110> direction of the opening 42 of the dot hole 4 on the wafer surface 11 is 1 to 1.10. When the ratio between the length L1 in the <100> direction and the length L2 in the <110> direction is larger than 1.10, that is when the L1 is too long, the (110) plane that is held between the (111) plane or the (311) plane and the like becomes narrow at the opening 42 of the dot hole, and therefore a change in film thickness becomes steep which causes stress and likely film separation.

The final dot hole 4 of the present embodiment more preferably has the angle α between 63 and 73 degrees, that is formed by the side surface 44 and the wafer surface 11 (or the bottom surface 43), in the cross-section in the <110> direction of the dot hole 4 illustrated in FIG. 5. By setting the angle steep within the range that can achieve alkaline etching, even when the dot hole is shallow by grinding the surface where the identification mark 5 exists in a device process, the shape of the opening 42 can be maintained and the film can be prevented from separating while maintaining visibility.

Also, the final dot hole 4 of the present embodiment more preferably has the angle β between 56 and 70 degrees, that is formed by the side surface 45 and the wafer surface 11 (or the bottom surface 43), in the cross-section in the <100> direction of the dot hole 4 illustrated in FIG. 6. By setting the angle steep within the range that can achieve alkaline etching, even when the dot hole is shallow by grinding the surface where the identification mark 5 exists in the device process, the shape of the opening 42 can be maintained and the film can be prevented from peeling off while maintaining visibility.

Returning to FIG. 2, the polishing step in step S5 of the present embodiment is a step of polishing both sides of the silicon wafer 1 after the etching process with the polishing solution containing the abrasive grains. This allows the surface of the silicon wafer 1 to be mirror polished. As a polishing slurry, the alkaline slurry containing colloidal silica can be used as polishing abrasive grains. This polishing step can perform a mirror-polish treatment to both sides of the silicon wafer 1 by fitting the silicon wafer 1 into a carrier, holding the wafer between the upper and lower plates with which polishing clothes are attached, pouring the slurry such as colloidal silica between the upper and lower plates and the wafer, and rotating the upper and lower plates and carrier in the opposite direction to each other. This reduces unevenness on the wafer surface which enables to obtain a wafer with increased flatness.

After the polishing step, a single-surface finish-polishing is performed where at least one surface of the silicon wafer is finish-polished one by one. This finish-polishing includes both of polishing only single surface and polishing both surfaces. When polishing both surfaces, after polishing one surface, the other surface is polished. This polishing brings the roughness of the surface on which the identification mark 5 is formed within a predetermined range. When the identification mark 5 is formed on the back surface of the silicon wafer 1 and the finish-polishing is performed only on the front surface, the front surface has less roughness compared to the back surface where the identification mark 5 is formed.

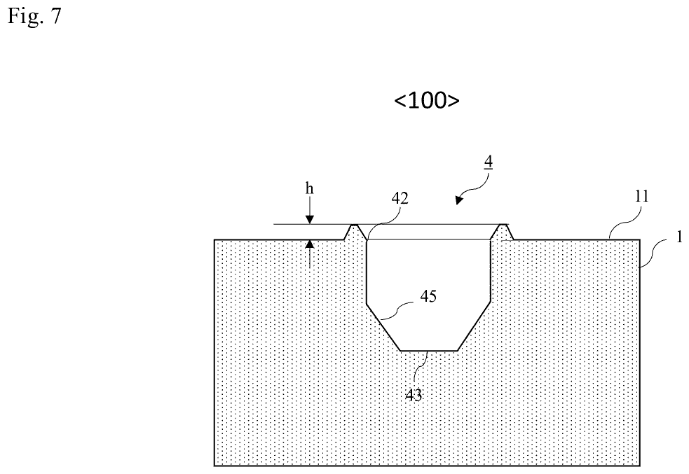

FIG. 7 is the cross-sectional view illustrating the silicon wafer 1 that has undergone the polishing step in FIG. 2. In the silicon wafer 1 of the present embodiment, more preferably, the projection height h of the opening 42 of the dot hole 4 on the wafer surface 11 is less than 25 nm from the wafer surface 11. With laser irradiation of the laser irradiation step of step S3 in FIG. 2, a circumferential edge of the opening 42 of the dot hole 4 is projected annularly. This projection of the opening 42 is removed by the alkaline etching step in step S4, but it has been found to be reproduced in the polishing step in step S5.

For example, the prior patent application by the applicant of the present application (Japanese Patent Laid-open Publication No. 2020-068231) states, under presumption that abrasive grains acting on a circumferential edge of a dot hole during a polishing treatment are insufficient, when a surface of a silicon wafer is polished while a polishing slurry is supplied between a polishing pad and the silicon wafer, the abrasive grains contained in the polishing slurry fall into the dot hole, which causes lacking of abrasive grains on the circumferential edge of the dot hole, and thus an amount of polish on the circumferential edge of the dot hole is reduced compared to the amount of polish in the other portion, resulting in the formation of a projection on the circumferential edge of the dot hole.

Therefore, in the silicon wafer 1 of the present embodiment, in order to make the projection height h of the opening 42 of the dot hole 4 on the wafer surface 11 less than 25 nm from the wafer surface 11, more preferably, as shown in FIG. 3B, the original shape 41 of the dot hole 4 is formed with the side surface with the small inclination such as the first original shape 411 to avoid lacking of abrasive grains on the circumferential edge of the dot hole 4. Accordingly, during the polishing step in step S5, the abrasive grains on the circumferential edge of the dot hole 4 can stay at the first original shape 411 portion, which can solve lacking the abrasive grains. This allows the projection height h of the opening 42 of the dot hole 4 on the wafer surface 11 to be less than 25 nm from the wafer surface 11, and the flatness of the laser mark printed portion 3 can be increased.

In contrast, in the silicon wafer 1 of the present embodiment, the projection height h of the opening 42 of the dot hole 4 on the wafer surface 11 may be 30 nm or more from the wafer surface 11. As shown in FIG. 7, by leaving the projection on the circumferential edge of the opening 42 of the dot hole 4, etchant accumulated in the dot hole 4 can be inhibited from running out. Accordingly, when the silicon wafer 1 is taken out from an etching tank, surrounding of the dot hole 4 can be inhibited from being etched unevenly by the etchant accumulated in the dot hole 4. In order to make the projection height h of the opening 42 of the dot hole 4 on the wafer surface 11 30 nm or more from the wafer surface 11, the original shape 41 of the dot hole 4 may be a side surface with a large inclination as shown in FIG. 3A, so that the abrasive grains are insufficient on the circumferential edge of the dot hole 4 for example.

As described above, according to the silicon wafer with the laser mark of the present embodiment, even when the identification mark 5 comprising of the dot holes 4 with the depth of 80 μm to 110 μm in the cross-section is formed on the silicon wafer 1 having the crystal plane orientation of (100), the dot holes 4 have less variations compared to the acid etching.

In addition to this, according to the silicon wafer with the laser mark of the present embodiment, the ratio between the length L1 in the <100> direction and the length L2 in the <110> direction of the opening 42 of the dot hole 4 on the wafer surface 11 is 1 to 1.10, and the length L1 in the <100> direction of the opening 42 is 80 μm to 110 μm, thereby the shape of the opening 42 of the dot hole 4 is continuously smooth although the shape depends on the crystal orientation. Accordingly, a concentration of stress to a corner of the opening 42 is controlled, and as a result, film can be inhibited from separating even when the treatment such as grinding is performed in a subsequent device process. Further, since the concentration of stress is controlled, even when a heat treatment is performed in the subsequent device process and the like, slip can be inhibited from occurring. Furthermore, since the dot hole 4 is as deep as 80 μm to 110 μm, visibility and discrimination are secured even when the grinding treatment or the like is performed in the subsequent device process and the like.

In addition, according to the manufacturing method of the silicon wafer with the laser mark of the present embodiment, when the identification mark 5 comprising of the dot holes 4 with the depth of 80 μm to 110 μm in the cross-section is formed on the silicon wafer 1 having the crystal plane orientation of (100), the laser light is irradiated on the wafer surface 11 of the silicon wafer 1 having the crystal plane orientation of (100), a plurality of stop holes (original shape 41 of the dot hole 4) with the depth of 80 μm to 110 μm are formed, after which the silicon wafer 1 is immersed in a potassium hydroxide solution with the concentration of 40 wt % or more to etch the wafer surface 11 and the stop holes (original form 41 of the dot hole 4) only by 5 to 15 μm thickness, and then the wafer surface 11 is polished, and therefore the identification mark 5 in a specific shape that is continuously smooth can be fabricated, although the shape of the opening 42 of the dot hole 4 depends on the crystal orientation.

Further, according to the silicon wafer with the laser mark of the present embodiment, the angle α formed by the side surface 44 and the wafer surface 11 (or the bottom surface 43) in the cross-section in the <110> direction of the dot hole 4 illustrated in FIG. 5 is between 63 and 73 degrees; the angle β formed by the side surface 45 and the wafer surface 11 (or the bottom surface 43) in the cross-section in the <100> direction of the dot hole 4 illustrated in FIG. 6 is between 56 and 70 degrees; and the shape of the dot hole 4 in the cross-section has a specific angle similar to square. Therefore, good visibility and discrimination are secured even when the laser mark printed portion 3 is ground or polished in the device process and the like.

### EXAMPLES

### Example 1

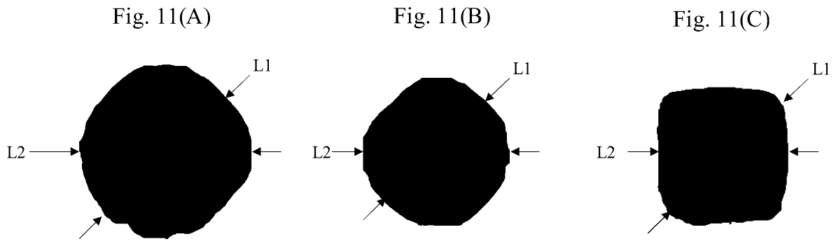

After forming the original shape 41 of the dot hole 4 by irradiating the laser light on the outer periphery of the silicon wafer having the crystal plane orientation of (100), the silicon wafer is immersed in a potassium hydroxide solution with a concentration of 40 wt % or more and the wafer surface 11 and the dot hole 4 are etched by a thickness of 10 μm, and thereby the silicon wafer 1 with the laser mark having the dot hole 4 with a depth D of 100.4 μm, a length L1 in the <100> direction of 95.8 μm, a ratio (L1/L2) between the length L1 in the <100> direction and a length L2 in the <110> direction of 1.04 is prepared. After forming a nitrogen film of 1 μm on this silicon wafer 1, a rapid thermal processing at 1000° C. is performed, and a state of the nitrogen film separation around the dot hole 4 was observed with an electron microscope. The results and conditions are shown in Table 1. Also, FIG. 11(A) is a binarized photo when a single dot hole 4 is observed in the front view.

### Example 2

The silicon wafer 1 with the laser mark was prepared under the similar conditions as in Example 1, except the dot hole 4 with the depth D of 87.9 μm, the length L1 in the <100> direction of 81.0 μm, the ratio (L1/L2) between the length L1 in the <100> direction and the length L2 in the <110> direction of 1.05, and the state of the film separation was observed. The results and conditions are shown in Table 1. Also, FIG. 11(B) is the binarized photo when the single dot hole 4 is observed in the front view.

### Comparative Example 1

The silicon wafer 1 with the laser mark was prepared under the similar conditions as in Example 1, except the dot hole 4 with the depth D of 89.2 μm, the length L1 in the <100> direction of 90.1 μm, the ratio (L1/L2) between the length L1 in the <100> direction and the length L2 in the <110> direction of 1.23, and the state of the film separation was observed. The results and conditions are shown in Table 1. Also, FIG. 11(C) is the binarized photo when the single dot hole 4 is observed in the front view.

TABLE 1

| | Ratio of | Diameter | | | Film |
|---|---|---|---|---|---|
| | diameter: | (μm) | Depth | Surrounding | sepa- |
| | <100>/<110> | <100> | (μm) | projection | ration |
| Example 1 | 1.04 | 95.8 | 100.4 | 20 | No |
| Example 2 | 1.05 | 81.0 | 87.9 | 19 | No |
| Comp. | 1.23 | 90.1 | 89.2 | 10 | Yes |
| Ex. 1 | | | | | |

### <<Consideration>>

When the depth D of the dot hole 4 is set 80 μm to 110 μm, the film separation was not observed when the ratio between the length L1 in the <100> direction and the length L2 in the <110> direction of the opening 42 of the dot hole 4 is 1 to 1.10 as in the Examples 1 and 2. In contrast, when L1/L2 exceeds 1.10 as in Comparative Example 1, the film separation was observed. As shown in the photo of FIG. 11(C) in the front view, the opening 42 of the dot hole 4 according to Comparative Example 1 has a substantially square shape with the large allowance by the alkaline etching. As a result, since the (110) plane at the corner that is held by the (111) plane is narrow, the change in film thickness becomes steep which causes stress and it is assumed that the film is likely to separate. The opening 42 of the dot hole 4 according to Example 1 illustrated in FIG. 11(A) and Example 2 illustrated in FIG. 11(B) is in an octagon shape with each vertex being circular, and the overall shape is similar to a circle. As a result, the change in film thickness is small and the shape is unlikely to cause concentration of stress.

### DESCRIPTION OF REFERENCE NUMERALS

1 . . . Silicon wafer
   11 . . . Wafer surface
2 . . . Notch
3 . . . Laser mark printed portion
4 . . . Dot hole
   41 . . . Original shape of dot hole
      411 . . . First original shape
      412 . . . Second original shape
   42 . . . Opening
   43 . . . Bottom surface
   44, 45 . . . Side surface
5 . . . Identification mark
L1 . . . Length in <100> direction
L2 . . . Length in <110> direction
α . . . Angle formed by bottom surface with side surface in cross-section along <110> direction
β . . . Angle formed by bottom surface with side surface in cross-section along <100> direction
h . . . Projection height for opening

1. A silicon wafer with a laser mark, the silicon wafer having a crystal plane orientation of (100) and an identification mark configured by a plurality of dot holes on a surface with a surface roughness of 0.15 to 0.60 nm, wherein
a ratio between a length in a <100> direction and a length in a <110> direction of an opening of the dot hole on a wafer surface is 1 to 1.10, and the length in the <100> direction of the opening is 80 μm to 110 μm,
a depth of the dot hole in a cross-section is 80 μm to 110 μm, and
a bottom surface of the dot hole is a flat surface of a (100) plane.

2. The silicon wafer with the laser mark according to claim 1, wherein an angle that is formed by a side surface and the wafer surface is 63 to 73 degrees in the cross-section in the <110> direction of the dot hole.

3. The silicon wafer with the laser mark according to claim 1, wherein an angle that is formed by a side surface and the wafer surface is 56 to 70 degrees in the cross-section in the <100> direction of the dot hole.

4. The silicon wafer with the laser mark according to claim 1, wherein a projection height of the opening is less than 25 nm from the wafer surface.

5. The silicon wafer with the laser mark according to claim 1, wherein the projection height of the opening is 30 nm or more from the wafer surface.

6. A manufacturing method of a silicon wafer with a laser mark comprising:
irradiating laser light on a wafer surface of the silicon wafer having a crystal plane orientation of (100) to form a plurality of stop holes with a depth of 80 μm to 110 μm;
then immersing the silicon wafer in a potassium hydroxide solution with a concentration of 40 wt % or more to perform etching of the wafer surface and the stop holes only by 5 to 15 μm thickness; and
then poshing the wafer surface.

7. The manufacturing method of the silicon wafer with the laser mark according to claim 6, wherein when irradiating the laser light on the wafer surface,
after irradiating the laser light with a first beam diameter, the laser light with a second beam diameter that is smaller than the first beam diameter is irradiated, or
after irradiating the laser light with the second beam diameter, the laser light with the first beam diameter is irradiated.

8. The manufacturing method of the silicon wafer with the laser mark according to claim 6, wherein when irradiating the laser light on the wafer surface, the laser light is irradiated with a single beam diameter.

9. The silicon wafer with the laser mark according to claim 2, wherein an angle that is formed by a side surface and the wafer surface is 56 to 70 degrees in the cross-section in the <100> direction of the dot hole.

10. The silicon wafer with the laser mark according to claim 2, wherein a projection height of the opening is less than 25 nm from the wafer surface.

11. The silicon wafer with the laser mark according to claim 2, wherein the projection height of the opening is 30 nm or more from the wafer surface.
